(19) United States
(12) Patent Application Publication
(10) Pub. No.: US 2020/0408841 A1
(43) Pub. Date: Dec. 31, 2020

(54) Connector Assembly, Battery Pole Terminal and Battery Sensor

(71) Applicant: CONTINENTAL AUTOMOTIVE GMBH, Hannover (DE)

(72) Inventor: Henryk Frenzel, Regensburg (DE)

(73) Assignee: CONTINENTAL AUTOMOTIVE GMBH, Hannover (DE)

(21) Appl. No.: 16/909,169

(22) Filed: Jun. 23, 2020

(30) Foreign Application Priority Data
Jun. 25, 2019 (DE) 10 2019 209 186.5

(51) Int. Cl. G01R 31/364; H01R 11/28; B60R 16/033

(52) U.S. Cl. CPC G01R 31/364; B60R 16/033; H01R 11/283

(57) ABSTRACT

The disclosure relates to a connector assembly for a battery sensor or a battery pole terminal with a connector segment for making contact with the battery sensor or the battery pole terminal. The connector segment includes a fastening element and a contact bolt. The contact bolt includes a socket for the fastening element and can be mounted at the fastening element. The contact bolt includes a contact surface which, when the contact bolt is in the mounted state at the fastening element, lies at the connector segment, and provides an electrical contact between the contact bolt and the connector segment. The disclosure further relates to a battery pole terminal and to a battery sensor having such a connector assembly.

### CROSS-REFERENCE TO RELATED APPLICATIONS

This application claims the benefit of German Patent Application 10 DE 2019 209 186.5, filed Jun. 25, 2019. The disclosure of the above application is incorporated herein by reference.

### TECHNICAL FIELD

The disclosure relates to a connector assembly for a battery sensor or a battery pole terminal and to a battery pole terminal and a battery sensor with such a connector assembly.

### BACKGROUND

A battery sensor or a battery pole terminal serves for making contact with the vehicle electrics in a vehicle, for example in a vehicle with a combustion engine or an electric motor, to the vehicle battery. The battery sensor or the battery pole terminal is placed on a battery pole and clamped to it so that a secure connection is established between the battery sensor and the battery pole terminal. A connector assembly is provided at the battery sensor or the battery pole terminal in which a cable for making contact with the vehicle electrics can be fastened.

The battery sensor or the battery pole terminal must ensure a reliable electrical contact between the vehicle electrics and the vehicle battery. This contact must be ensured reliably even in the presence of mechanical influences occurring in the vehicle, for example vibrations or a vehicle impact, and also in the presence of tensile stress on the cable. A good electrical contact must furthermore be ensured in order to be able to carry the currents occurring during vehicle operation reliably.

Usually the connector assembly includes a bolt to which the cable is fastened with a lug. The bolt is usually pressed into a connector segment. The bolt can, for example, also be a threaded bolt, while the lug of the cable is fastened to the bolt with a nut. However, these fastenings are very laborious to realize, in particular in the presence of the temperature changes that occur in the vehicle.

The cable can, alternatively, be directly soldered to the connector segment and/or fastened with clamps. This type of connection is, however, also very laborious. In addition, a non-releasable connection is established, which makes an exchange of the battery pole terminals or of the battery sensor more difficult.

### SUMMARY

The disclosure provides a connector assembly for a battery sensor or a battery pole terminal that has a high mechanical stability as well as enabling an easy and reliable assembly of a cable. It should also be possible to convey the high currents that arise in vehicle operation, for example, in electric vehicles, reliably and with low losses. The disclosure also provides a battery sensor and a battery pole terminal with these properties. Universal application of the connector assembly is also desired, which means that it should be possible for it to be adapted easily to different cable connectors or different installation situations. A connector assembly for a battery sensor or a battery pole terminal with a connector segment for making contact with the battery sensor or the battery pole terminal and with a contact bolt is provided. The connector segment includes a fastening element, while the contact bolt includes a socket for the fastening element and can be mounted at the fastening element. The contact bolt includes a contact surface which, when the contact bolt is in the mounted state at the fastening element, lies at the connector segment, and provides an electrical contact between the contact bolt and the connector segment.

Implementations of the disclosure may include one or more of the following optional features. In some implementations, the contact bolt is thus not directly mounted at the connector segment, but at a fastening element that is provided at the connector segment. In addition, the electrical contact does not take place, or not exclusively, via the fastening element, but via the contact surface of the contact bolt which lies immediately flat against the connector segment. The holding function for the contact bolt and the contact function are thus separated from one another, so that the respective functional regions of the connector segment or of the contact bolt can be matched to the respective function.

The fastening element and the socket of the contact bolt may be designed such that a high mechanical stability can be provided. For example, the shape of the socket and of the fastening element may enable an ideal adaptation to the mechanical stresses that arise. In particular, the dimensioning can be carried out independently of making electrical contact.

Both the contact surface and a corresponding lay-on surface at the connector segment may be designed such that current transfer takes place with the lowest possible loss. The size of the contact surface may be matched to the currents to be transferred.

Through the use of various contact bolts or contact bolts with different external dimensions, an adaptation to different cable connectors or installation situations is also possible. An adaptation to different currents that are to be transferred is also possible through an appropriate dimensioning of the contact surface.

A contact geometry may be provided at the contact surface which includes regions protruding toward the connector segment. The fastening element and the socket may be so designed that the contact surface is pressed against the connector segment in order to create the most reliable electrical contact possible. Due to the protruding regions, a higher compression force partially develops, through which the contact between the contact surface and the connector segment is ensured. In addition, these regions may be designed such that they contribute to the mechanical stability of the connection between the contact bolt and the connector segment in that, for example, they prevent the contact bolt from twisting around the fastening element.

For example, the fastening element is a bolt that protrudes from the connector segment, and the socket is essentially cylindrical in design. The bolt may protrude perpendicularly from the connector segment. The fastening element and the socket are dimensioned such that the bolt may be pushed into the socket. This permits an easy, reliable assembly into the contact bolt at the connector segment.

In order to establish a reliable mechanical connection, the fastening element includes, for example, an external thread and a corresponding internal thread is provided in the socket of the contact bolt. The contact bolt may thereby easily be screwed onto the fastening element. Due to the screwing on, the compression force with which the contact surface is pressed against the connector segment may also be adjusted very precisely and reliably, so that both a mechanical and also an electrical contact is reliably ensured.

To be able to screw the contact bolt onto the fastening element a torque transfer profile may be provided at the contact bolt, such as a square, hexagonal or multi-edge profile. In some examples, a torque transfer profile for which a corresponding special tool is required may be used, in order to prevent a manipulation or unwanted release of the connection between the contact bolt and the connector segment. The contact surface can, for example, be provided at the lower face of the torque transfer profile that faces towards the connector segment.

The contact bolt may include a flange protruding perpendicularly with respect to the longitudinal axis of the contact bolt, at which the contact surface is provided. By way of this flange, the contact surface can be given any desired form, such as enlarged. The mechanical stability, in response to tensile forces on the contact bolt, can be improved through the flange, since this flange can support the contact bolt additionally via the flange at the connector segment. The torque transfer profile can be formed at this flange.

The fastening element may be fastened at the connector segment in a variety of ways. The fastening element can, for example, extend through the connector segment and be supported with a support surface on the side of the connector assembly that is opposite to the contact bolt. If the contact bolt is screwed onto the fastening element, the connector segment is clamped between the support surface and the contact surface, such as the flange, whereby a reliable mechanical and electrical hold is ensured.

In some implementations, a battery pole terminal is furthermore provided for making contact with a battery pole of its vehicle battery having an annular segment that encloses at least in segments a cylindrical or conical accommodating space for the battery pole in a circumferential direction. The annular segment includes an interruption with opposing edges in respect of the circumferential direction, where a socket for a clamping element is provided at each of the edges. The battery pole terminal furthermore includes a connector assembly, described above, that is electrically and mechanically connected to the annular segment.

To achieve the object a battery sensor for detecting at least one battery parameter is furthermore provided, with a battery pole terminal for making contact with a battery pole of its vehicle battery, with an annular segment that at least partially encloses a cylindrical or conical accommodating space for the battery pole in a circumferential direction, where the annular segment has an interruption in the sense of the circumferential direction with opposing edges, while a socket for a clamping element is provided at each of the edges, with at least one detection apparatus for detecting at least one battery parameter, and with a connector assembly, described above, wherein the connector assembly is in electrical contact with the battery pole terminal or the detection apparatus.

The battery sensor may include a current detection apparatus and/or a voltage detection apparatus that connects the annular segment and the connector assembly together electrically.

The battery sensor includes, for example, at least one measuring resistor that connects the annular segment and the connector assembly together electrically.

The details of one or more implementations of the disclosure are set forth in the accompanying drawings and the description below. Other aspects, features, and advantages will be apparent from the description and drawings, and from the claims.

### DESCRIPTION OF DRAWINGS

FIG. 1 shows a perspective illustration of a battery sensor according to the prior art,

FIGS. 2a and 2b show different perspective views of an exemplary battery sensor;

FIG. 3 shows a perspective view of an exemplary battery sensor with a fastening element;

FIGS. 4a and 4b show the exemplary contact bolt of FIGS. 2a and 2b respectively;

FIG. 5 shows a detailed view of the exemplary battery sensor of FIGS. 2a and 2b in the region of the connector segment and of the contact bolt;

FIGS. 6a and 6b show different views of the exemplary battery sensor of FIG. 5;

FIG. 7 shows a sectional view through the exemplary battery sensor of FIG. 4 in the region of the connector segment and of the contact bolt; and

FIG. 8 shows a second example of a contact bolt.

Like reference symbols in the various drawings indicate like elements.

### DETAILED DESCRIPTION

A battery sensor 10′ with a battery pole terminal 12′ for making contact with a battery pole of a vehicle battery, a detection apparatus 14′ for detecting at least one battery parameter, and a connector assembly 16′ for making contact with a cable are shown in FIG. 1.

The battery pole terminal 12′ includes an annular segment 18′ with a cylindrical or conical accommodating space 20′ for accommodating a battery pole that includes an interruption 22′. A clamping element 24′ is provided at the interruption 22′ to reduce the diameter of the accommodating space 20′ and thus to clamp the battery pole terminal onto a battery pole.

The detection apparatus 14′ includes a measuring resistor 26′ that connects the battery pole terminal 12′ and the connector assembly 16′ together electrically. The detection apparatus 14′ includes, moreover, a housing 28′ in which measurement electronics are provided, for example for the detection of a voltage drop across the measuring resistor 26′ in order to determine the battery current from the voltage drop and the known electrical resistance of the measuring resistor 26′.

The connector assembly 16′ includes a connector segment 30′ that is electrically connected to the measuring resistor 26′. The connector assembly 16′ includes, moreover, a bolt 32′ with a flange 34′. The bolt 32′ is pressed through a hole 35′ of the connector segment 30′ until the flange 34′ lies against the connector segment 30′.

A cable may be fastened to the bolt 32′, for example by a lug. A cable lug is, for example, secured with a nut.

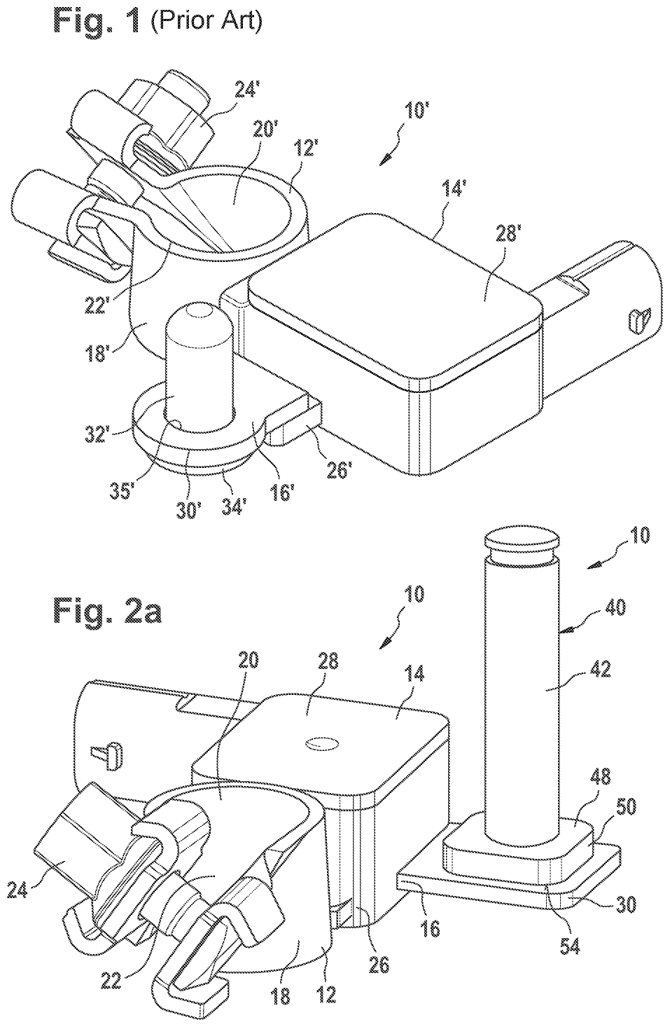

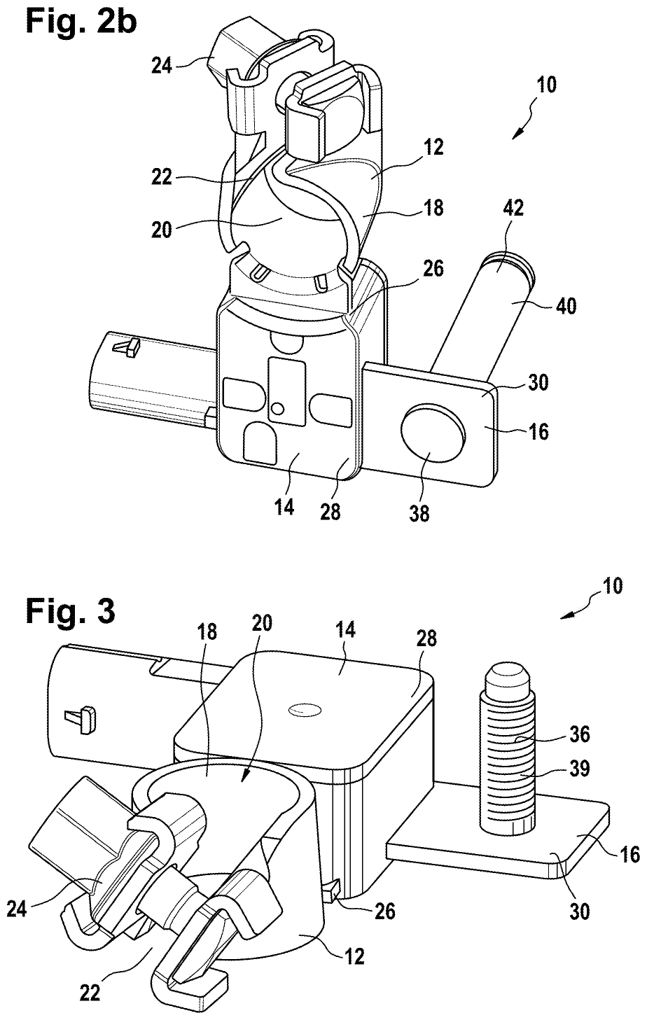

FIGS. 2a and 2b show a battery sensor 10 that includes a fastening element 36 designed as a bolt instead of the bolt 32′ (see FIG. 3). Analogously to the contact bolt 32′, the fastening element 36 extends through the connector segment 30 and is supported at it with a flange 38. The fastening element 36 can, however, be fastened at the connector segment 30 in any other way.

As can be seen, particularly through a comparison between FIGS. 1 and 3, the fastening element 36 is smaller in dimensions than the contact bolt 32′, and has a smaller diameter as well as a smaller length. An external thread 39 may be provided on the outer surface of the fastening element 36.

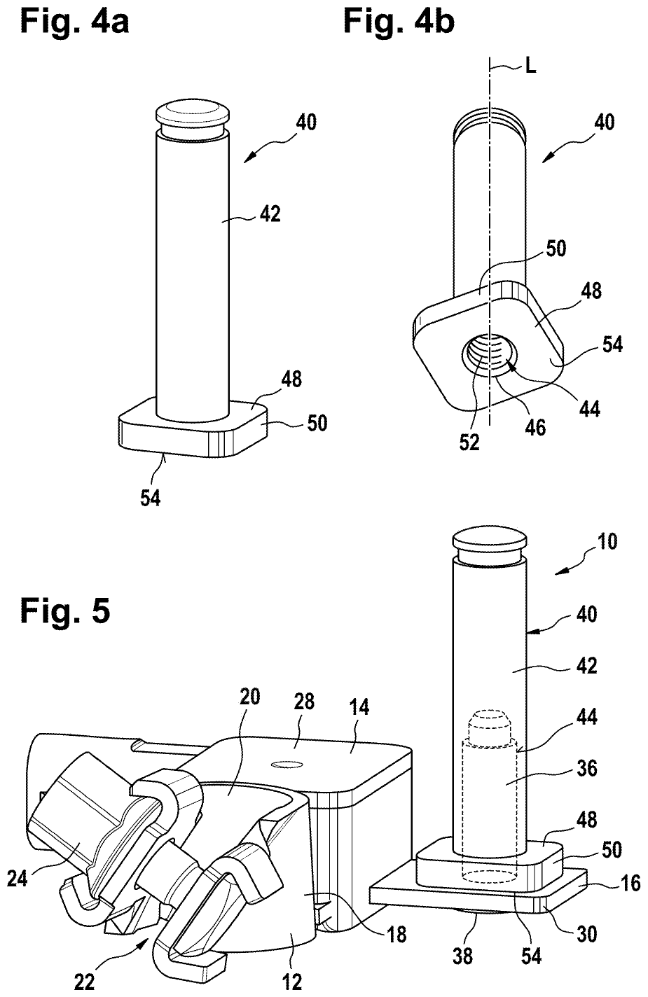

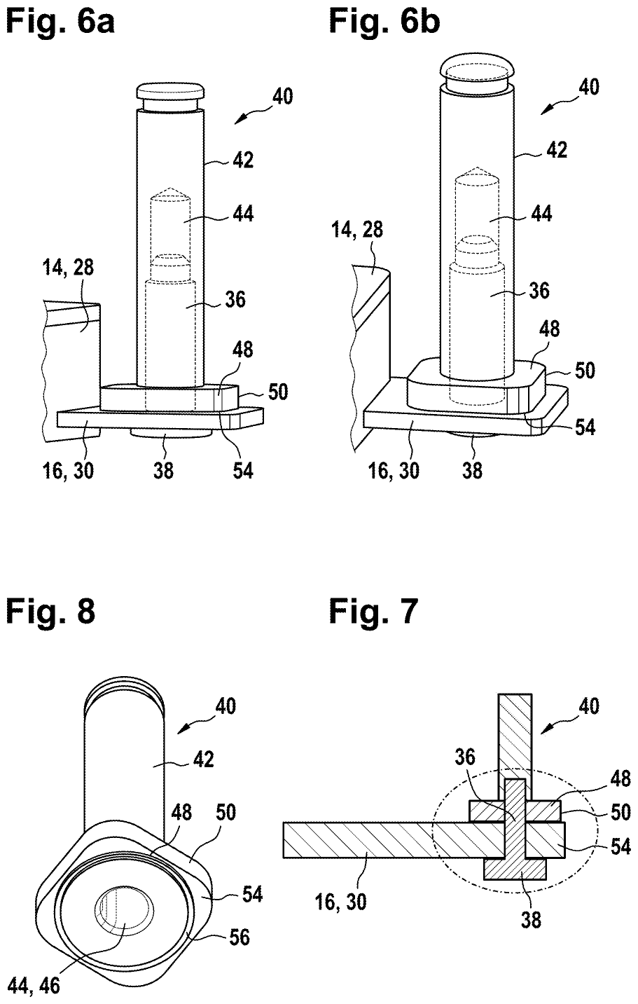

The connector assembly 16 of the battery sensor 10 includes, moreover, a contact bolt 40 shown in detail in FIGS. 4a and 4b. The contact bolt 40 has an essentially cylindrical main body 42 in which an essentially cylindrical socket 44 is provided that ends in an opening 46. At the opening 46, the contact bolt 40 includes a flange 48 which, in the form of embodiment shown here, is essentially square in form and extends perpendicularly to the longitudinal axis L of the main body 42. The outer side of the flange 48 forms a torque transfer profile 50 that represents a tool socket. An internal thread 52 corresponding to the external thread 38 is provided in the socket 44.

The contact bolt 40 is adapted to a shape of a connector element of a cable, or can be individually selected for the particular application of the battery sensor 10.

To assemble the connector assembly 16, the contact bolt 40 is pushed with the socket 44 onto the fastening element 36, and the internal thread 52 screwed together with the external thread 38. A tool may be applied to the flange 48 or to the torque transmission transfer profile 50 for this purpose. The contact bolt 40 is screwed on until the flange 48 lies flat against the connector segment 30 with a contact surface 54 that is formed on the lower side facing the connector segment 30. By turning the contact bolt 50 further, the contact surface 54 may be pressed against the connector segment 30.

In addition, the connector segment 30 is thereby clamped between the flange 38 of the fastening element 32 and the flange 48 of the contact bolt 40.

Through the contact surface 54 that lies against the connector segment 30 or is pressed against it, an electrical contact is established between the contact bolt 40 and the connector segment 30. The mechanical hold of the contact bolt 40 is, on the other hand, established by the fastening element 32 and the socket 44, so that the mechanical hold and the electrical contact are functionally separated from one another.

The fastening element 32 serves, for example, exclusively or predominantly for the mechanical support of the contact bolt, so that this is dimensioned exclusively from the mechanical point of view. In some examples, the material of the form of the fastening element 32 can be selected depending on the desired mechanical properties.

The flange 48 allows the contact bolt 40 to make contact with the connector segment 30. The contact surface 54 is accordingly dimensioned in accordance with the currents to be transferred, and is manufactured from an appropriate material with high conductivity. In addition, the flange 48 may have a supporting function in order to ensure better load transfer to the connector segment 30 if tensile forces act on the contact bolt 40.

The connector segment 30 and the contact bolt 40 may be coated with a corrosion protection layer, for example with tin. Such a corrosion protection layer is relatively soft, so that the contact surface 54, when pressed against the connector segment 30, presses into the soft corrosion layer of the connector segment 30, whereby a very good electrical connection is established. The corrosion protection layer is, in addition, not interrupted, so that a reliable corrosion protection is ensured.

The contact surface 54 can be designed to be flat. It is, however, also possible that it additionally includes a contact geometry 56 with projections. These projections can, for example, press into the material of the connector segment 30, whereby the electrical contact is improved and/or the mechanical hold is improved. The projections can, for example, prevent twisting and consequent loosening of the contact bolt 40.

The contact bolt 40 may also be fastened to the fastening element 30 in another way. It is only necessary to ensure that a mechanical hold is established between the fastening element 30 and the contact bolt 40, and that the contact surface 54 is pressed against the connector segment 32. The contact bolt 40 can, in particular, also include a different tool socket, in particular a different torque transfer profile. This can, for example, be provided at the end of the contact bolt 40 opposite to the flange 52.

A number of implementations have been described. Nevertheless, it will be understood that various modifications may be made without departing from the spirit and scope of the disclosure. Accordingly, other implementations are within the scope of the following claims.

### LIST OF REFERENCE SIGNS

10, 10′ Battery sensor
12, 12′ Battery pole terminal
14, 14′ Detection apparatus
16, 16′ Connector assembly
18, 18′ Annular segment
20, 20′ Accommodating space
22, 22′ Interruption
24, 24′ Clamping element
26, 26′ Measuring resistor
28, 28′ Housing
30, 30′ Connector segment
32′ Bolt
34′ Flange
36 Fastening element
38 Flange
40 Contact bolt
42 Main body
44 Socket
46 Opening
48 Flange
50 Torque transfer profile
52 Internal thread
54 Contact surface
56 Contact geometry
L Longitudinal direction of the main body

What is claimed is:

1. A connector assembly for a battery sensor or a battery pole terminal, the connector assembly comprising:
a connector segment for making contact with the battery sensor or the battery pole terminal, the connector segment comprises:
a fastening element, and
a contact bolt, wherein the contact bolt includes:
a socket for the fastening element and can be mounted at the fastening element, and
a contact surface, when the contact bolt is in a mounted state at the fastening element, the contact surface lies at the connector segment and provides an electrical contact between the contact bolt and the connector segment.

2. The connector assembly as claimed in claim 1, wherein a contact geometry is provided at the contact surface which comprises regions protruding toward the connector segment.

3. The connector assembly as claimed in claim 1, wherein the fastening element is a bolt that protrudes from the connector segment, and the socket has a cylindrical shape.

4. The connector assembly as claimed in claim 3, wherein the bolt protrudes perpendicularly from the connector segment.

5. The connector assembly as claimed in claim 1, wherein the fastening element comprises an external thread and a corresponding internal thread is provided in the socket of the contact bolt.

6. The connector assembly as claimed in claim 1, wherein the contact bolt comprises a flange protruding perpendicularly with respect to a longitudinal axis of the contact bolt, at which the contact surface is provided.

7. The connector assembly as claimed in claim 1, wherein a torque transfer profile, is provided at the contact bolt.

8. The connector assembly as claimed in claim 7, wherein the torque transfer profile includes at least one of: a square, hexagonal and multi-edge profile.

9. The connector assembly as claimed in claim 1, wherein the fastening element extends through the connector segment and is supported with a support surface on a side of the connector segment that is opposite to the contact bolt.

10. A battery pole terminal for making contact with a battery pole of a vehicle battery, the battery pole terminal comprising:
a cylindrical or conical accommodating space for the battery pole in a circumferential direction;
an annular segment that encloses the cylindrical or conical accommodating space, the annular segment comprises:
an interruption with opposing edges in respect of the circumferential direction,
a socket for a clamping element is provided at each of the edges,
a connector assembly electrically and mechanically connected to the annular segment, the connector assembly comprising:
a connector segment for making contact with a battery sensor or a battery pole terminal, the connector segment comprises:
a fastening element, and
a contact bolt including:
a socket for the fastening element and can be mounted at the fastening element, and
a contact surface, when the contact bolt is in a mounted state at the fastening element, the contact surface lies at the connector segment and provides an electrical contact between the contact bolt and the connector segment.

11. A battery sensor for detecting at least one battery parameter, with a battery pole terminal for making contact with a battery pole of its vehicle battery, with an annular segment that at least partially encloses a cylindrical or conical accommodating space for the battery pole in a circumferential direction, wherein the annular segment has an interruption in the sense of the circumferential direction with opposing edges, while a socket for a clamping element is provided at each of the edges, with at least one detection apparatus for detecting at least one battery parameter, and with a connector assembly wherein the connector assembly is in electrical contact with the battery pole terminal or the detection apparatus, the connector assembly comprising:
a connector segment for making contact with the battery sensor or the battery pole terminal, the connector segment comprises:
a fastening element, and
a contact bolt including:
a socket for the fastening element and can be mounted at the fastening element, and
a contact surface, when the contact bolt is in a mounted state at the fastening element, the contact surface lies at the connector segment and provides an electrical contact between the contact bolt and the connector segment.

12. The battery sensor as claimed in claim 11, wherein the battery sensor comprises a current detection apparatus and/or a voltage detection apparatus that connects the annular segment and the connector assembly together electrically.

13. The battery sensor as claimed in claim 11, wherein the battery sensor comprises at least one measuring resistor that connects the annular segment and the connector assembly together electrically.
